(19) United States
(12) Patent Application Publication
(10) Pub. No.: US 2013/0061902 A1
(43) Pub. Date: Mar. 14, 2013

(54) SOLAR POWER SYSTEM

(71) Applicant: JAMES D. QUINN, Waterford (CA)

(72) Inventor: JAMES D. QUINN, Waterford (CA)

(21) Appl. No.: 13/228,354

(22) Filed: Sep. 8, 2011

(51) Int. Cl. H01L 31/042

(52) U.S. Cl. 136/244

(57) ABSTRACT

The solar power system includes one or more solar panels removably installed atop the roof or upper surface of a motor vehicle or non-motorized vehicle (e.g., a trailer). In one embodiment, the vehicles (semi-trailers, passenger buses, vans, etc.) are parked in a yard or terminal, and the electrical power produced by the solar panels atop the vehicles is delivered to a fixed local distribution system in the yard or terminal area. The power produced may be used for the normal electrical needs of the operation, and any excess power may be sold to the local municipal electric company or other relatively wide area electrical grid. In another embodiment, the solar panels generate electrical power while the vehicles are traveling, and the electrical power is stored aboard the vehicles until the vehicles reach a destination where the power can be transferred to the fixed local distribution system for use.

### BACKGROUND OF THE INVENTION

1. Field of the Invention

The present invention relates generally to electrical power generation and distribution systems, and particularly to a solar power system incorporating solar cells deployed atop large motor vehicles and the like, and to subsequent storage and distribution of the electrical power so generated.

2. Description of the Related Art

The world in general, and more industrially developed nations in particular, are ever increasingly reliant upon electrical energy. Yet, generally speaking the generation of electrical power requires the consumption of energy in other forms, with coal fueled power plants being a primary source of electrical energy in many parts of the world. While great strides have been made in reducing the pollution byproducts of such coal fueled power plants, the consumption of natural resources and the remaining pollution produced by such plants is of course undesirable.

As a result, alternative means of producing electrical power have been developed. One such means comprises nuclear-fueled power plants. While nuclear power plants produce no emissions other than heat, the expended nuclear fuel is difficult to dispose of, and the potential for disaster at such nuclear power plants is ever present, even if unlikely. Hydroelectric and wind generation are also used to produce electrical power as “clean” methods of generating power, i.e., non-polluting methods, other than the construction and maintenance of their physical structures. However, relatively few sites are suitable for efficient hydroelectric and wind generation of electrical power, and the cost of producing a given quantity of electrical power from such sources is often considerably higher than the cost of power produced from an established coal burning power plant.

Nevertheless, as the cost of electrical power production continues to climb, various alternative power production means are becoming more attractive. One such means is the use of photoelectric or photovoltaic cells, also known as solar cells. Solar cells are known to produce electrical energy directly from the light that reaches the photocells, which might be considered “free energy,” once the photocell array has been paid for and installed. While the initial cost of such photocells has been relatively high in the past, increasing production efficiencies are resulting in the cost of electrical power produced by such photocells slowly approaching the cost of electrical power produced by other principles, thus making the generation of electrical power by solar cells a more attractive option than in the past.

As the production of electrical power by means of solar cells becomes more economically attractive, more and more sites are being considered for the installation of such solar cells. These sites are generally fixed or stationary, e.g., on rooftops, etc., where the area exposed to the sun is not otherwise being utilized. A less common installation is upon electrically powered motor vehicles, so that the electrical energy may be used to provide at least some of the power for the operation of the vehicle. However, the relatively low amount of solar energy received per unit area and the relatively low efficiency of most solar cells renders such installations impractical for conventional motor vehicles. In any event, the collection of solar power to this point has either been by stationary installations delivering their electrical power to corresponding fixed or stationary points of electrical energy consumption, or by mobile installations where the mobile device consumes the electrical energy produced to provide motive power.

Thus, a solar power system solving the aforementioned problems is desired.

### SUMMARY OF THE INVENTION

The solar power system provides a means for collecting otherwise wasted solar energy that falls upon the roofs or tops of motor vehicles and delivering the resulting electrical energy to a fixed, stationary electrical power grid. The solar power system comprises the installation of a flexible solar panel containing a plurality of photovoltaic or solar cells on the roof or upper surface of one or more relatively large vehicles, such as semi-trailers, vans, and passenger buses. The solar power produced by the panel(s) is collected for distribution and use in a fixed, stationary electrical power grid.

In one embodiment, the solar panel equipped vehicles are parked in a bus or truck terminal or yard, and their solar panels are electrically connected to a local network that delivers the electrical power to a distribution system in the terminal or yard, where the power may be used by the terminal or yard for normal electrical power needs. Any excess electrical power produced may be transferred to the conventional municipal or other wide area electrical grid for use.

In another embodiment, the solar panels generate electricity while the vehicle is traveling. As the electricity produced cannot be transferred to a stationary grid or system while the vehicle is in motion, the electricity is stored on board the vehicle for later transfer to a local or wide area electrical grid when the vehicle arrives at a suitable terminal or other location capable of receiving the stored electrical energy from the vehicle. The energy storage means aboard the vehicle may comprise any of a number of principles, e.g., electrochemical storage batteries, high efficiency capacitors, kinetic storage (flywheels), etc.

These and other features of the present invention will become readily apparent upon further review of the following specification and drawings.

### BRIEF DESCRIPTION OF THE DRAWINGS

FIG. 1 is an environmental perspective view of an exemplary embodiment of a solar power system according to the present invention, implemented in a truck yard.

FIG. 2 is an environmental perspective view of an exemplary second embodiment of a solar power system according to the present invention, implemented at a loading dock.

FIG. 3 is a plan view of an exemplary display panel for monitoring the electrical power output of a solar power system according to the present invention.

FIG. 4 is a block diagram illustrating the various paths for electrical power in a solar power system according to the present invention from generation to distribution.

FIG. 5 is a perspective view of solar panels in a solar power system according to the present invention mounted on a semi-trailer.

FIG. 6 is a perspective view of solar panels in a solar power system according to the present invention mounted on a passenger bus.

FIG. 7 is a perspective view of solar panels in a solar power system according to the present invention mounted on a van-type truck.

Similar reference characters denote corresponding features consistently throughout the attached drawings.

### DETAILED DESCRIPTION OF THE PREFERRED EMBODIMENTS

The solar power system provides for the collection of solar energy from vehicle rooftops, and the conversion of that energy to electrical power for storage and/or distribution to a local or wide area power grid. The system may utilize parked vehicles, or may utilize vehicles in motion. The generated electrical power may be stored aboard the vehicle for distribution when the vehicle is parked.

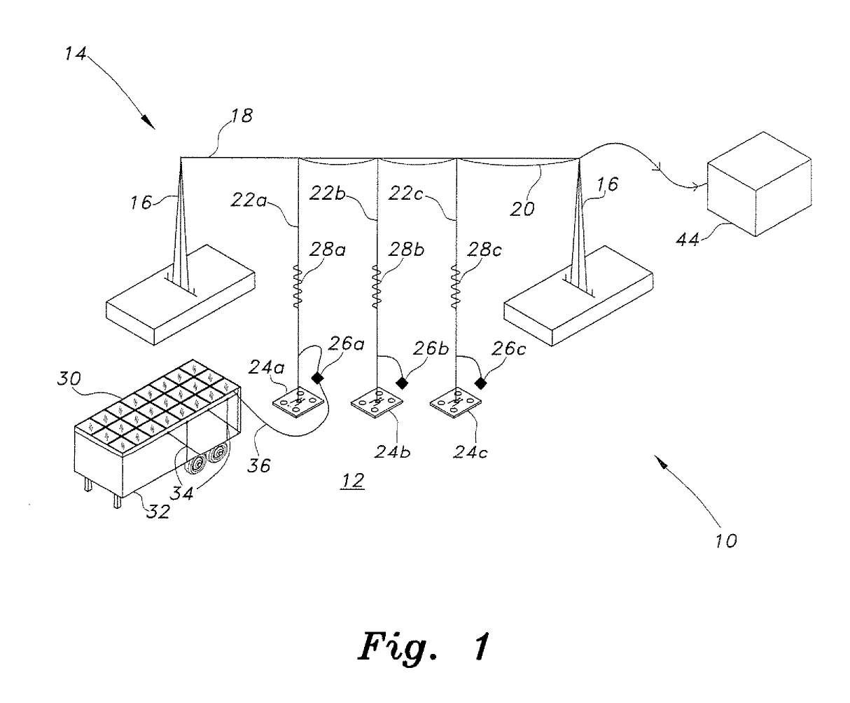

FIG. 1 of the drawings provides an illustration of an exemplary solar power system 10, as such a system might be installed or disposed in a vehicle yard or terminal 12 (e.g., truck terminal, bus storage yard, etc.). The yard 12 includes a fixed, local power distribution network 14 comprising at least two towers 16 or other elevated points and a support cable 18 extending between the two towers 16. An electrical cable or line 20 is suspended from the support cable 18. The electrical cable 20 comprises a number of electrically separate lines according to the number of separate positions provided in the yard from which electrical power may be drawn from vehicles parked at those positions.

A plurality of drop line cords 22a, 22b, 22c extend from the electrical cable 20. Each of the cords 22a-22c is anchored to a corresponding anchor point 24a, 24b, 24c, etc. Each of the cords or lines 22a-22c terminates in a corresponding electrical connector, e.g., 26a, 26b, 26c (shown schematically in FIG. 1), enabling an electrical source to be connected to each connector to supply electrical power to the local electrical network 14. Each of the drop line cords 22a-22c includes some slack therein, which is taken up by corresponding springs 28a, 28b, 28c, etc. This system anchors each of the drop lines or cords 22a-22c securely to prevent them from blowing loosely in the wind, while still providing sufficient slack to allow for some movement in the overhead support cable 18 and/or contact by a vehicle being parked in the yard.

A flexible solar panel 30 or grid of panels is removably secured to the roof or upper surface of each vehicle intended to interface with the solar power system 10, e.g., the semi-trailer vehicle 32 illustrated in FIG. 1. The flexible solar panel 30 may be secured to the top of the trailer 32 by conventional tiedown straps or lines 34 or by any other suitable means. The flexible solar panel 30 (or grid of panels) includes a large number of conventional flexible solar cells thereon, enabling the solar panel 30 to be drawn over the sides and/or other irregularities of the upper surface of the vehicle to which it has been applied. Each flexible solar panel 30 includes an electrical connector, i.e., a power cord 36, extending therefrom. The power cord 36 may be removably connected to a corresponding electrical connector, e.g., connector 26a, to transfer the electrical power produced by the solar panel 30 to the network 14. The drop line cords 22a-22c and their corresponding anchors 24a-24c are preferably spaced to allow the positioning of a conventional vehicle (e.g., bus, semi-trailer, etc.) between adjacent cords. This allows a plurality of such vehicles to be parked in the yard with each being connected to a corresponding electrical connector 26a-26c from a corresponding drop line cord 22a-22c. It will be understood that the local power distribution network 14 includes an interface that steps up the voltage delivered by the cable 20 and converts the voltage delivered by the cable to the type of voltage (e.g., a.c. voltage) that can be practically used by the network 14, while isolating the panel(s) 30 from power supplied by the network 14.

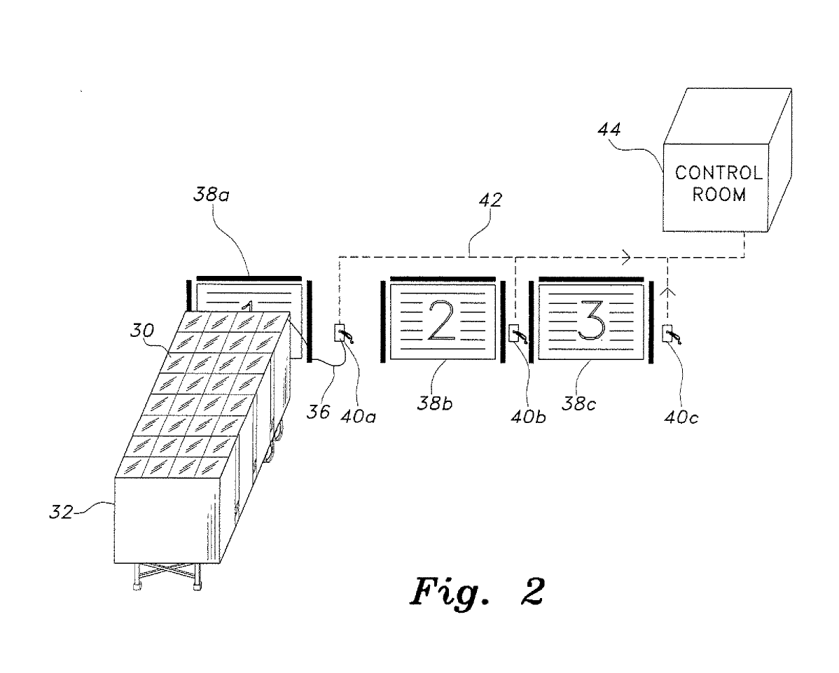

FIG. 2 provides an illustration of an alternative system for collecting electrical power from vehicle rooftop solar panels. In FIG. 2, the semi-trailer 32 with its removably installed flexible solar panel(s) 30 is shown backed up to the first loading dock 38a of a row of such loading docks 38a, 38b, 38c. Each of the loading docks 38a-38c includes a loading dock receptacle and electrical cord 40a, 40b, 40c immediately adjacent to the corresponding loading dock 38a-38c. The cords 40a-40c are spring-loaded to retract them to their respective receptacles when not in use, but to allow their extension to connect to a corresponding electrical power cord 36 extending from the solar panel(s) 30 atop the vehicle 32. The various loading dock electrical receptacles and their cords 40a-40c are electrically connected to a fixed, local power distribution network 42, similar in function to the power distribution network 14 of the embodiment of FIG. 1.

In both the embodiments of FIG. 1 and FIG. 2, the power distribution networks 14 and 42 connect electrically to a control and/or distribution facility 44. The control and/or distribution facility 44 receives the electrical power produced by the various solar panels, e.g., solar panel 30, and redistributes that power for use throughout a localized electrical grid for distributing electrical power throughout the vehicle terminal or yard as needed, e.g., for operating lights, electrically powered loading dock doors, and other electrical equipment. Alternatively, in the event that more electrical power is produced than may be needed by the local grid of the vehicle terminal, the surplus electrical power may be transmitted to a wide area public utility electrical grid or the like for sale thereto. Such systems are well known in the art of electrical power production and distribution, and need not be described in detail here.

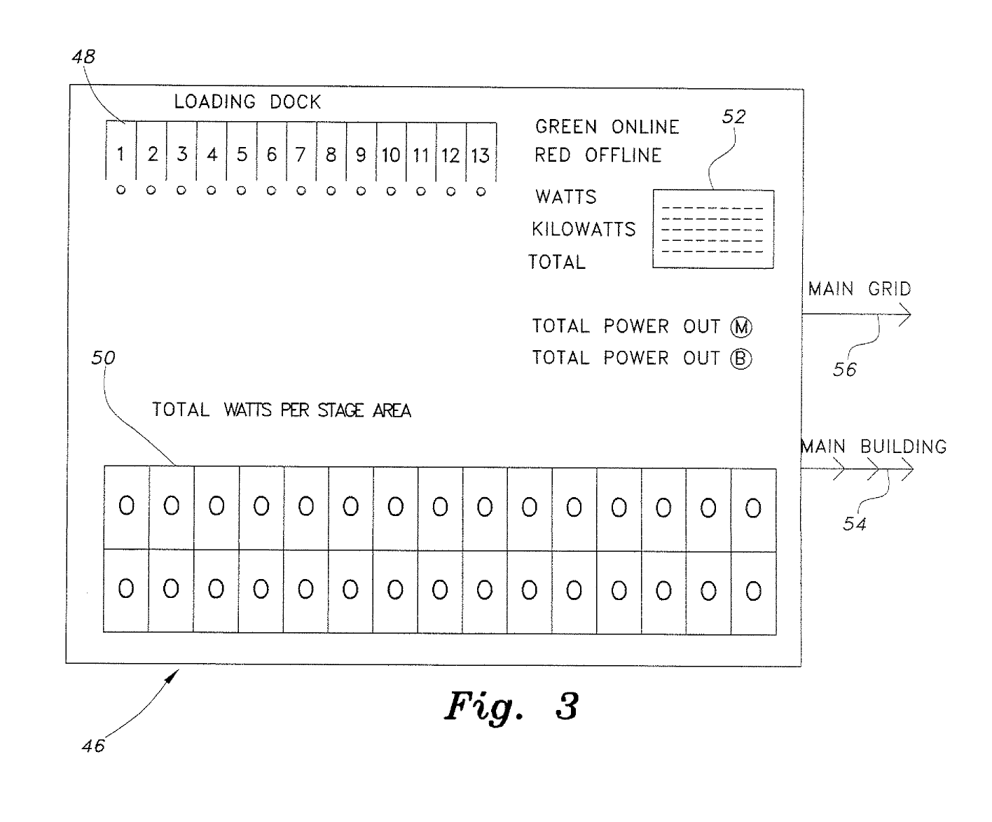

FIG. 3 provides an illustration of an exemplary monitoring panel or display 46 that may be used with any of the embodiments of the solar panel system described herein. The monitoring panel or display 46 includes a sub panel 48 in the upper left portion thereof representing the loading dock positions, e.g., loading dock positions one through thirteen. Obviously, the number of positions may be adjusted to correspond with any practical number of loading docks at the vehicle storage yard or terminal. Each position includes a light therewith, with the light having two different colors. A green light indicates that the solar panel of a vehicle is connected to the system, i.e., “online,” while a red light indicates that the specific circuit is open, i.e., “offline.” The colors are exemplary, and may be adjusted as desired.

A second sub-panel 50 across the lower portion of the panel or display 46 represents the various positions in the yard or terminal staging area, i.e., the positions served by the drop lines or cords 22a, 22b, 22c in the exemplary illustration of FIG. 1. Each position may be indicated by a light to show whether the position is active, i.e., having a vehicle solar panel connected thereto, or inactive. Alternatively, or in addition to such indicator lights, each position may display the electrical power (wattage) output of each position.

A third sub-panel 52 provides for the display of the electrical power output (in watts or kilowatts) of the loading dock and staging area positions as indicated on the sub-panels 48 and 50, and a display of the total wattage output over a predetermined period of time. The total power output may be distributed to the local grid or network, e.g., the network 14 shown in FIG. 1 and/or the network 42 of FIG. 2, via the “Main Building” line 54 (to the local distribution network or grid provided from the distribution facility 44), or alternatively excess electrical output may be sold to the larger area or public utility grid, as indicated by the “Main Grid” line 56.

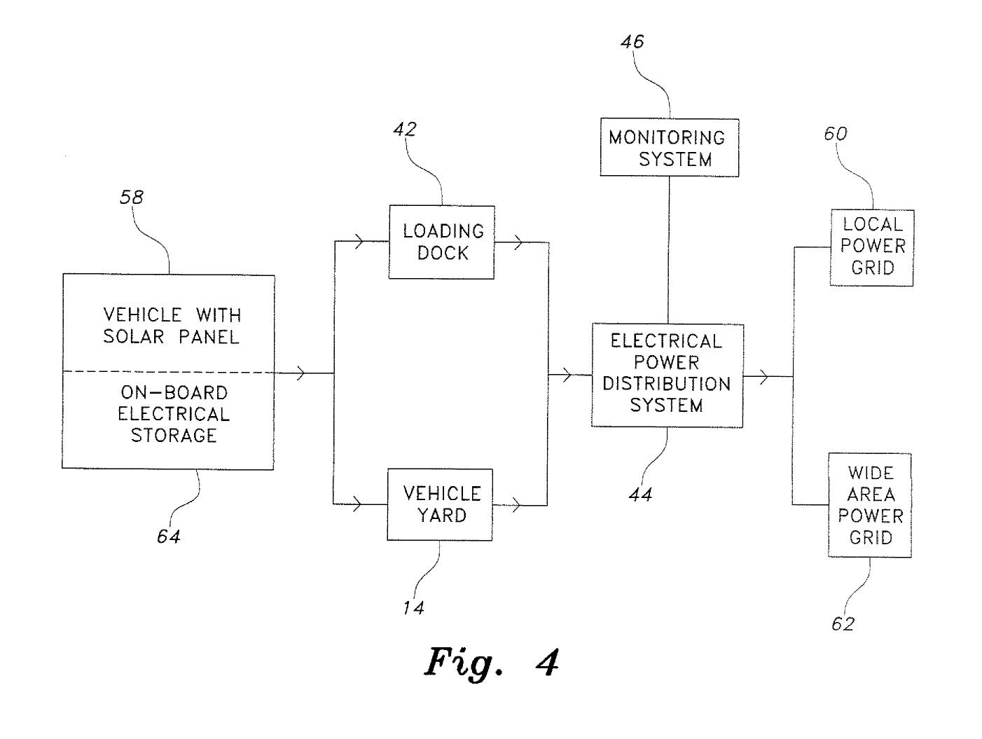

FIG. 4 is a block diagram that very briefly describes the various elements or components of the various embodiments of the solar power system and the flow of electrical power through the system. Initially, a vehicle and solar panel combination 58 (e.g., the semi-trailer 32 of FIGS. 1 and 2 or other vehicle equipped with the solar panel 30 or other solar panel configuration) is connected to the fixed local electrical power distribution network or grid 14 of the vehicle yard or, alternatively, to the fixed local power distribution network or grid 42 of the loading dock. Both of these networks or grids 14 and 42 deliver electrical power to a conventional electrical power distribution system, as controlled by the control or distribution facility 44. The system may be monitored by the monitoring panel or display 46 exemplified in FIG. 3 of the drawings. The power distribution system or facility 44 delivers the electrical power produced by the vehicle and solar panel 58 to either the local power network or grid 60 of the vehicle terminal or yard, or alternatively, to the larger scale network or grid 62 of the public electric utility serving the area.

FIG. 4 also briefly describes an alternative means of generating or producing electrical power in accordance with the solar power system. The various vehicles of the system, e.g., the semi-trailer 30 of FIGS. 1 and 2, etc., may be equipped with an on-board electrical storage system 64, as indicated with the vehicle and solar panel combination 58 in FIG. 4. Such an on-board electrical storage system 64 may be conventional in nature, e.g., electrical storage batteries (lead-acid, lithium, etc.), high-efficiency capacitors, or perhaps mechanical energy storage in the form of one or more flywheels, or some combination of the above principles. Each of the above energy storage means is well known and conventional, and need not be described in further detail. The incorporation of any of the above energy storage means with the vehicle enables the vehicle to store electrical energy produced by its solar panels while the vehicle is in motion. When the vehicle is delivered to the terminal or yard 14, it may be connected electrically to the local grid or network 14 or 42 as described above using a conventional power cord or cable extending from the energy storage means to an appropriate receptacle 26a-26c (FIG. 1) or 40a-40c (FIG. 2) in the manner used to connect the solar panel 30 directly to the fixed local electrical power grid of FIG. 1 or FIG. 2.

FIGS. 5 through 7 of the drawings illustrate further embodiments of the solar power system, primarily illustrating exemplary vehicle types that might be used with the system. FIG. 5 of the drawings illustrates a semi-trailer 30, much like the trailer 30 illustrated in FIGS. 1 and 2. It will be noted that such trailers 30 are conventionally provided with marker or position lights 66. In some cases, the flexible solar panel may extend beyond the roof or upper surface of the vehicle 30, and depend partially down the upper sides of the vehicle. This may result in the depending portions of the solar panel, e.g., the panel 68 of FIG. 5, covering the upper marker lights of the vehicle 30. Accordingly, the solar panel 68 may be provided with clearance areas comprising transparent lighting display panels 70 disposed along the various vertically depending portions of the solar panel 68 when installed upon the vehicle 30.

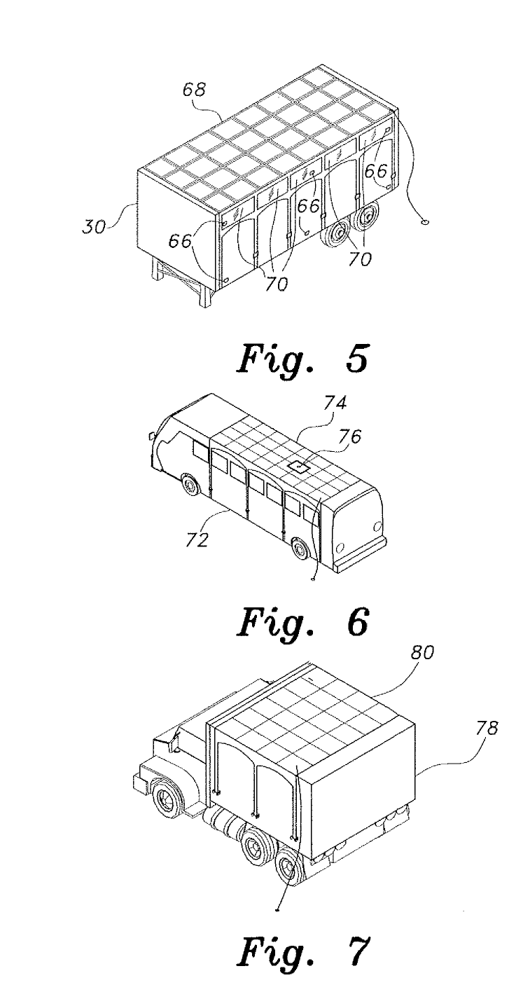

FIG. 6 of the drawings illustrates another type of vehicle that may be used with the solar power system, i.e., a passenger bus 72 (school bus, tour bus, etc.) and flexible solar panel 74 therewith. Such buses often include emergency escape hatches in their roofs, and this is particularly true in the case of school buses. Accordingly, the flexible solar panel 74 may be provided with a clearance area comprising a roof opening 76 positioned congruently with the roof escape hatch of the vehicle 72. Such roof openings 76 may be provided for other vehicles having openings or discontinuities in their roof structures, e.g., large recreational vehicles with roof-mounted air conditioning units, etc.

FIG. 7 of the drawings illustrates yet another vehicle type to which a flexible solar panel may be temporarily and removably installed, the vehicle comprising a van-type truck 78. The flexible solar panel 80 temporarily and removably installed thereon may be configured substantially like the flexible solar panel 30 of FIGS. 1 and 2, but may have a different aspect ratio in accordance with the length and width of the roof or upper surface of the van 78.

Accordingly, the solar power system in its various embodiments provides means for utilizing the otherwise unused areas of the roofs or upper surfaces of motorized and non-motorized vehicles as those roofs or upper surfaces are exposed to the sun. The provision for on-board electrical storage extends the functionality of the system beyond the vehicle storage yard or terminal, allowing the vehicles to produce electrical power from solar energy even as they travel down the highway. While the electrical power generated per vehicle over a relatively short period of time, e.g., a day or so, may not be great, the gathering of the electrical power produced by a large number of solar panel equipped vehicles over perhaps several weeks results in a meaningful amount of electrical power produced that may assist in reducing the load required of a conventional electrical power plant.

It is to be understood that the present invention is not limited to the embodiments described above, but encompasses any and all embodiments within the scope of the following claims.

I claim:

1. A solar power system, comprising:
at least one solar panel adapted for removable attachment to an upper surface of a vehicle;
a fixed, local electrical power distribution network; and
an electrical connector extending from the solar panel, the electrical connector being adapted for temporary connection to the local electrical power distribution network;
whereby electrical power produced by the solar panel is delivered to the local electrical power distribution network.

2. The solar power system according to claim 1, further comprising:
means for temporarily storing electrical power generated by the at least one solar panel on board the vehicle; and
a second electrical connector extending from the means for temporarily storing electrical power, the second electrical connector being adapted for temporary connection to the local electrical power distribution network;
whereby electrical power produced by the flexible solar panel and temporarily stored by the means for temporarily storing electrical power is delivered to the local electrical power distribution network.

3. The solar power system according to claim 1, further comprising a vehicle terminal, the fixed, local electrical power distribution network being disposed therewith.

4. The solar power system according to claim 1, wherein the local power distribution network includes a connection point selected from the group consisting of at least one overhead cable having at least one drop line cord extending therefrom and at least one loading dock receptacle cord.

5. The solar power system according to claim 1, wherein the solar panel includes clearance areas selected from the group consisting of transparent lighting display panels and roof openings.

6. The solar power system according to claim 1, further comprising an electrical monitoring system communicating electrically with the local electrical power distribution network.

7. The solar power system according to claim 1, further comprising at least one vehicle selected from the group consisting of semi-trailers, passenger buses, and vans, the at least one solar panel being mounted on the at least one vehicle.

8. A solar power system, comprising:
at least one solar panel adapted for removable attachment to an upper surface of a vehicle;
means for temporarily storing electrical power generated by the at least one solar panel on board the vehicle;
a fixed, local electrical power distribution network; and
an electrical connector extending from the means for temporarily storing electrical power, the electrical connector being adapted for temporary connection to the local electrical power distribution network;
whereby electrical power produced by the at least one solar panel and temporarily stored by the means for temporarily storing electrical power is delivered to the local electrical power distribution network.

9. The solar power system according to claim 8 further comprising a second electrical connector extending from the solar panel, the second electrical connector being adapted for temporary connection to the local electrical power distribution network, whereby electrical power produced by the at least one solar panel is delivered to the local electrical power distribution network.

10. The solar power system according to claim 8, further comprising:
a vehicle terminal, the fixed, local electrical power distribution network being disposed therewith; and
a second electrical connector extending from the solar panel, the second electrical connector being adapted for temporary connection to the local electrical power distribution network;
whereby electrical power produced by the at least one solar panel is delivered to the local electrical power distribution network.

11. The solar power system according to claim 8, wherein the local power distribution network includes a connection point selected from the group consisting of at least one overhead cable having at least one drop line cord extending therefrom and at least one loading dock receptacle cord.

12. The solar power system according to claim 8, wherein the flexible solar panel includes clearance areas selected from the group consisting of transparent lighting display panels and roof openings.

13. The solar power system according to claim 8, further comprising an electrical monitoring system communicating electrically with the local electrical power distribution network.

14. The solar power system according to claim 8, further comprising at least one vehicle selected from the group consisting of semi-trailers, passenger buses, and vans, the at least one solar panel being mounted on the at least one vehicle.

15. A solar power system, comprising:
a vehicle terminal;
a fixed local electrical power distribution network disposed at the vehicle terminal;
at least one solar panel adapted for removable attachment to an upper surface of a vehicle; and
an electrical connector extending from the at least one solar panel, the electrical connector being adapted for temporary connection to the local electrical power distribution network;
whereby electrical power produced by the at least one solar panel is delivered to the local electrical power distribution network.

16. The solar power system according to claim 15, further comprising:
means for temporarily storing electrical power generated by the at least one solar panel on board the vehicle; and
a second electrical connector extending from the means for temporarily storing electrical power, the second electrical connector being adapted for temporary connection to the local electrical power distribution network;
whereby electrical power produced by the at least one solar panel and temporarily stored by the means for temporarily storing electrical power is delivered to the local electrical power distribution network.

17. The solar power system according to claim 15, wherein the local power distribution network includes a connection point selected from the group consisting of at least one overhead cable with at least one drop line cord extending therefrom and at least one loading dock receptacle cord.

18. The solar power system according to claim 15, wherein the at least one solar panel includes clearance areas selected from the group consisting of transparent lighting display panels and roof openings.

19. The solar power system according to claim 15, further comprising an electrical monitoring system communicating electrically with the local electrical power distribution network.

20. The solar power system according to claim 15, further comprising at least one vehicle selected from the group consisting of semi-trailers, passenger buses, and vans, the at least one solar panel being mounted on the at least one vehicle.
